(19) United States
(12) Patent Application Publication
(10) Pub. No.: US 2026/0271666 A1
(43) Pub. Date: Sep. 10, 2026

(54) SEMICONDUCTOR MANUFACTURING APPARATUS AND WAFER DEVIATION PREVENTING PAD

(71) Applicant: Kioxia Corporation, Tokyo (JP)

(72) Inventors: Miho KOTANI, Yokkaichi Mie (JP); Taijiro NARITA, Yokkaichi Mie (JP)

(73) Assignee: Kioxia Corporation, Tokyo (JP)

(21) Appl. No.: 19/326,765

(22) Filed: Sep. 12, 2025

(30) Foreign Application Priority Data
Mar. 5, 2025 (JP) 2025-034697

(51) Int. Cl. H01L 21/68; B25J 9/16; B25J 11/00; B25J 15/00; H01L 21/687

(52) U.S. Cl. CPC H10P 72/50; B25J 11/0095; B25J 15/0014; H10P 72/7602; B25J 9/1682

(57) ABSTRACT

A semiconductor manufacturing apparatus includes: a storage chamber that stores a wafer; a robot that unloads the wafer from the storage chamber, and transfers the wafer to a processing chamber; a robot arm attached to the robot; a transfer portion that is attached to the robot arm and transfers the wafer; and a plurality of holders that are attached to the transfer portion and hold the wafer. The holder includes a planar portion, and a head portion disposed on the planar portion. The wafer is in planar contact, at a wafer end, with the planar portion, and a transfer deviation of the wafer is prevented by the head portion.

### CROSS-REFERENCE TO RELATED APPLICATION

This application is based upon and claims the benefit of priority from Japanese Patent Application No. 2025-034697, filed Mar. 5, 2025, the entire contents of which are incorporated herein by reference.

### FIELD

Embodiments described herein relate generally to a semiconductor manufacturing apparatus, and a wafer deviation preventing pad.

### BACKGROUND

For example, in a chemical dry etching (CDE) apparatus, a chemical vapor deposition (CVD) apparatus, and other semiconductor manufacturing apparatuses, a wafer transfer pick (pick) moves in a vacuum transfer module (VTM). The wafer transfer pick is provided with a pad for fixing and holding a wafer.

If an end of a wafer repetitively comes into point contact with a certain point on a pad, a temporal change occurs on the pad. Combined factors due to smoothing, hardening, and deformation of the surface of the pad result in the loss of a function of holding a wafer, and causes a wafer deviation. If the wafer is transferred in the deviating state, the wafer might fall onto a wafer transfer pick and/or in a vacuum-side module, a wafer transfer error might occur, and a defect might occur in the wafer.

### BRIEF DESCRIPTION OF THE DRAWINGS

FIG. 1A is a perspective view of a wafer storage chamber (FOUP) used for a semiconductor manufacturing apparatus according to a first embodiment.

FIG. 1B is a perspective view of a FOUP and a transfer portion that are used for the semiconductor manufacturing apparatus according to the first embodiment.

FIG. 2 is a horizontal sectional view of the FOUP used for the semiconductor manufacturing apparatus according to the first embodiment.

FIG. 3 is a plan view of the semiconductor manufacturing apparatus according to the first embodiment.

FIG. 4 is a plan view of a transfer portion that transfers a wafer and holders that hold the wafer in a processing chamber, in the semiconductor manufacturing apparatus according to the first embodiment.

FIG. 5 is a sectional view taken along line I-I in FIG. 4, and is a diagram for illustrating a transfer method for the wafer in the processing chamber in the semiconductor manufacturing apparatus according to the first embodiment (Part 1).

FIG. 6 is a sectional view for illustrating the transfer method for the wafer in the processing chamber in the semiconductor manufacturing apparatus according to the first embodiment (Part 2).

FIG. 7A is a sectional view illustrating the relationship between the holder attached to the transfer portion and the wafer in the semiconductor manufacturing apparatus according to the first embodiment.

FIG. 7B is a sectional view of the holder on which the wafer is mounted in the semiconductor manufacturing apparatus according to the first embodiment.

FIG. 7C is a diagram illustrating a situation where the holder is attached to and detached from the transfer portion in the semiconductor manufacturing apparatus according to the first embodiment.

FIG. 8A is a sectional view of a configuration where a holder according to a modified example 1 is attached to the transfer portion in the semiconductor manufacturing apparatus according to the first embodiment.

FIG. 8B is a sectional view of a holder according to a modified example 2 and a situation of attachment to and detachment from the transfer portion in the semiconductor manufacturing apparatus according to the first embodiment.

FIG. 9 is a sectional view of a structure of a holder according to a modified example 3 in the semiconductor manufacturing apparatus according to the first embodiment.

FIG. 10A is a sectional view of a configuration where a holder is attached to a transfer portion having a positioning structure in the semiconductor manufacturing apparatus according to a second embodiment.

FIG. 10B is a plan view of the transfer portion that has the positioning structure in FIG. 10A.

FIG. 10C is a sectional view taken along line II-II in FIG. 10B.

FIG. 11A is a plan view of a configuration of a holder in the semiconductor manufacturing apparatus according to a third embodiment.

FIG. 11B is a sectional view of a configuration where the holder is attached to a transfer portion having a positioning structure in the semiconductor manufacturing apparatus according to the third embodiment.

FIG. 11C is a three-dimensional perspective view of the structure of a head portion of the holder in the semiconductor manufacturing apparatus according to the third embodiment.

FIG. 12 is a plan view of a configuration where the wafer is mounted on the holders in the semiconductor manufacturing apparatus according to the third embodiment.

FIG. 13A is a sectional view of a configuration where a holder is attached to a transfer portion having positioning structures in a semiconductor manufacturing apparatus according to a fourth embodiment.

FIG. 13B is a plan view of the transfer portion that has the positioning structures in FIG. 13A.

FIG. 13C is a sectional view taken along line III-III in FIG. 13B.

FIG. 14A is a first application example of the holder in the semiconductor manufacturing apparatus according to the fourth embodiment.

FIG. 14B is a second application example of the holder in the semiconductor manufacturing apparatus according to the fourth embodiment.

FIG. 14C is a third application example of the holder in the semiconductor manufacturing apparatus according to the fourth embodiment.

FIG. 14D is a fourth application example of the holder in the semiconductor manufacturing apparatus according to the fourth embodiment.

FIG. 15A is a plan view of the configuration of a holder in a semiconductor manufacturing apparatus according to a fifth embodiment.

FIG. 15B is a sectional view of a configuration where the holder is attached to a transfer portion in the semiconductor manufacturing apparatus according to the fifth embodiment.

FIG. 15C is a plan view of the transfer portion in FIG. 15B.

FIG. 15D is a sectional view taken along line IV-IV in FIG. 15B.

FIG. 16 is a plan view of a configuration where the wafer is mounted on the holders in the semiconductor manufacturing apparatus according to the fifth embodiment.

FIG. 17A is a first application example of the holder in the semiconductor manufacturing apparatus according to the fifth embodiment.

FIG. 17B is a second application example of the holder in the semiconductor manufacturing apparatus according to the fifth embodiment.

FIG. 17C is a third application example of the holder in the semiconductor manufacturing apparatus according to the fifth embodiment.

FIG. 17D is a fourth application example of the holder in the semiconductor manufacturing apparatus according to the fifth embodiment.

FIG. 18A is a plan view of a configuration where the wafer is mounted on the holders in the semiconductor manufacturing apparatus according to the fifth embodiment (first application example).

FIG. 18B is a plan view of a configuration where the wafer is mounted on the holders in the semiconductor manufacturing apparatus according to the fifth embodiment (second application example).

### DETAILED DESCRIPTION

One or more embodiments may provide a semiconductor manufacturing apparatus and a wafer deviation preventing pad that fix and hold a wafer on a wafer transfer pick, and prevent the wafer from causing a transfer deviation.

In general, according to one embodiment, a semiconductor manufacturing apparatus includes: a storage chamber that stores a wafer; a robot that unloads the wafer from the storage chamber, and transfers the wafer to a processing chamber; a robot arm attached to the robot; a transfer portion that is attached to the robot arm and transfers the wafer; and a plurality of holders that are attached to the transfer portion and hold the wafer. The holder includes a planar portion, and a head portion disposed on the planar portion. The wafer is in planar contact, at an end, with the planar portion, and a transfer deviation of the wafer is prevented by the head portion.

Embodiments are described below with reference to the drawings. Note that in the following description, the same and similar components are assigned the same symbols, and the description of components and the like having once been described is omitted as appropriate. In the following description, the surface normal direction of a transfer portion 11 is assumed as a Z-axis direction, and a plane perpendicular to the Z-axis direction is assumed as an XY plane (this similarly applies to the followings). The Y-axis direction is a direction in which the transfer portion 11 is transferred into a processing chamber 23. The X-axis direction is a direction perpendicular to the Z-axis direction and the Y-axis direction. The X-axis direction and the Y-axis direction described above are only examples. Note that in the embodiments of the present invention, terms that identify upward and downward, such as “upward” and “downward”, are used for the sake of convenience. For example, the positive direction of the Z-axis direction is assumed as “upward”, and the negative direction is assumed as “downward”.

### Configuration of Semiconductor Manufacturing Apparatus

### (FOUP)

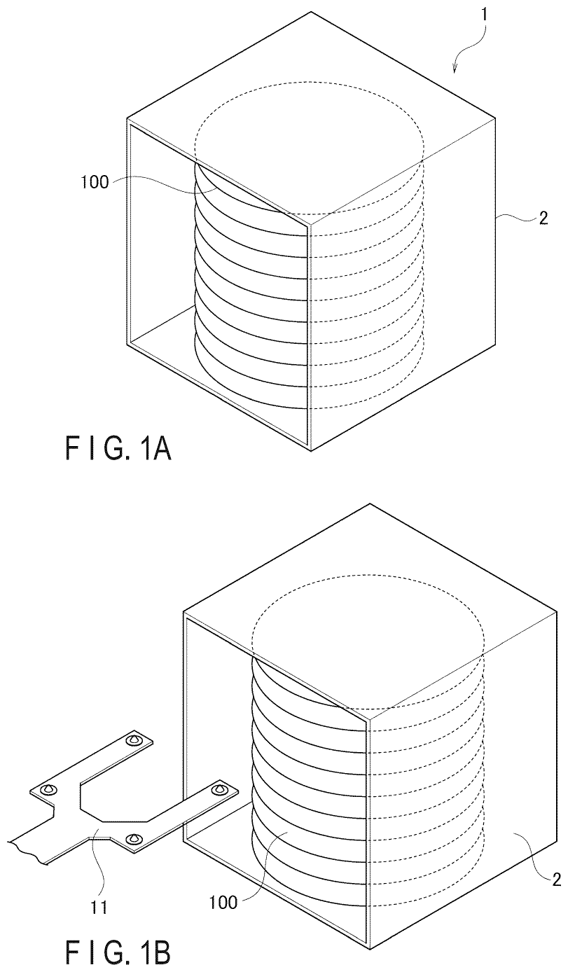

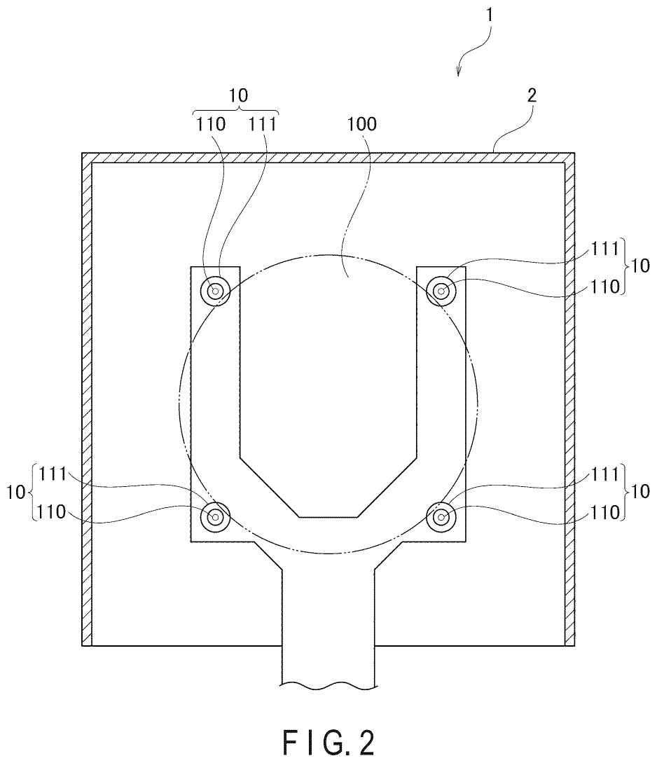

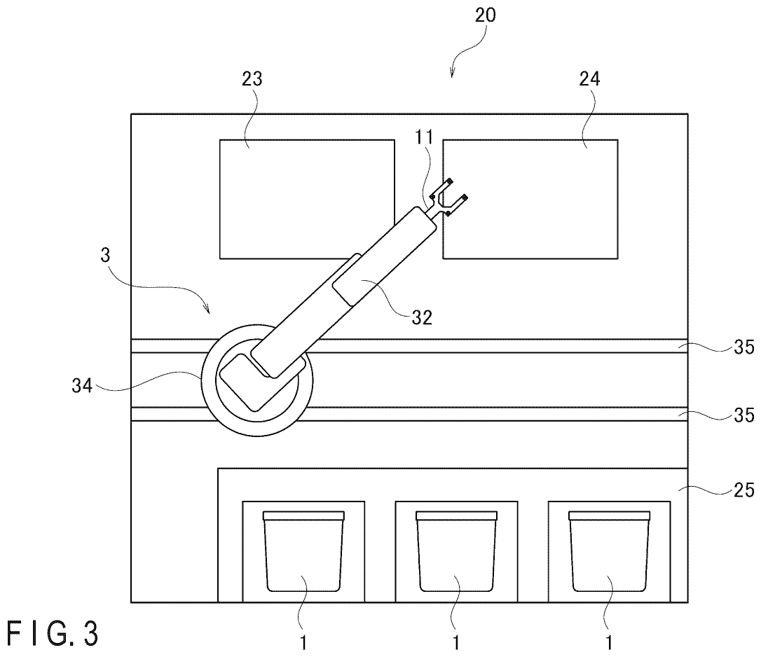

An FOUP (Front Opening Unified Pod) is described. FIG. 1A is a perspective view of a wafer storage chamber (FOUP) 1 used for a semiconductor manufacturing apparatus according to an embodiment. FIG. 1B is a perspective view of the FOUP 1 and a transfer portion 11 connected to a robot. FIG. 2 is a horizontal sectional view of the FOUP 1. FIG. 3 is a plan view of the semiconductor manufacturing apparatus according to the embodiment.

The FOUP 1 is a wafer carrier that stores a semiconductor wafer (hereinafter, simply called a “wafer”) that is transferred from the processing apparatus to another processing apparatus.

The FOUP 1 includes a carrier main body 2 that can internally store a plurality of (e.g., 25) wafers 100. The carrier main body 2 includes multiple stages of slots on which wafers are respectively mounted on a one-by-one basis. As shown in FIG. 1B, the transfer portion 11 is inserted between the slots. As shown in FIG. 2, the transfer portion 11 includes holders (pads) 10 that support the peripheral portion (bevel portion) of each wafer 100 at a plurality of positions (here, four positions). Each holder 10 includes a planar portion 111, and a head portion 110. The gap of upper and lower slots of the FOUP 1 is about 10 mm, for example. Bevel processing (curving) is applied to the wafer end.

### Semiconductor Manufacturing Apparatus

FIG. 3 is a plan view of a semiconductor manufacturing apparatus 20 according to a first embodiment. The semiconductor manufacturing apparatus 20 includes: a stage 25 on which a plurality of FOUPs 1 can be mounted; and processing chambers 23 and 24. Here, the processing chambers 23 and 24 are dedicated chambers for executing a chemical dry etching (CDE) or chemical vapor deposition (CVD) step. The chambers may execute a foreign matter removal step, and also serve as chambers that execute another manufacturing step. For example, the foreign matter removal step may be executed in a chamber in which an ashing step by a plasma process is performed. Typically, a dry etching step often uses a carbon film as a mask material to be used in processing. After the dry etching step, the ashing step is executed to remove the mask material that is unnecessary in the following steps. In the ashing step, for example, carbon is removed from the wafer by the plasma process of causing a gas containing oxygen as a principal component to become plasma in a state where the wafer is heated. Accordingly, the processing chambers 23 and 24 may also serve as chambers in which the ashing step is executed.

Furthermore, the semiconductor manufacturing apparatus 20 includes a robot 3 that transfers the wafer 100 in the FOUP 1 between the stage 25 and the processing chambers 23 and 24. The robot 3 includes: a base 34 that is rotatable around the vertical axis as a rotation axis; a robot arm 32 that includes a plurality of joints that extend from the base 34; and a transfer portion 11 that is provided at a distal end of the robot arm 32 and can hold the wafer 100 in the FOUP 1.

A mechanism that can grasp the FOUP 1 is provided at the distal end of the robot arm 32. However, the illustration on the diagram is herein omitted. The robot 3 takes out the wafer 100 in the FOUP 1 from the stage 25 while moving along the rails 35 in the semiconductor manufacturing apparatus 20, sets it in the processing chamber 23, takes out the processed wafer 100 from the processing chamber 23, and sets it in the processing chamber 24. Subsequently, the robot 3 takes out the processed wafer 100, and returns it to the stage 25. These robot 3, stage 25, and processing chambers 23 and 24 are provided in the semiconductor manufacturing apparatus 20, which is highly airtight and sealed.

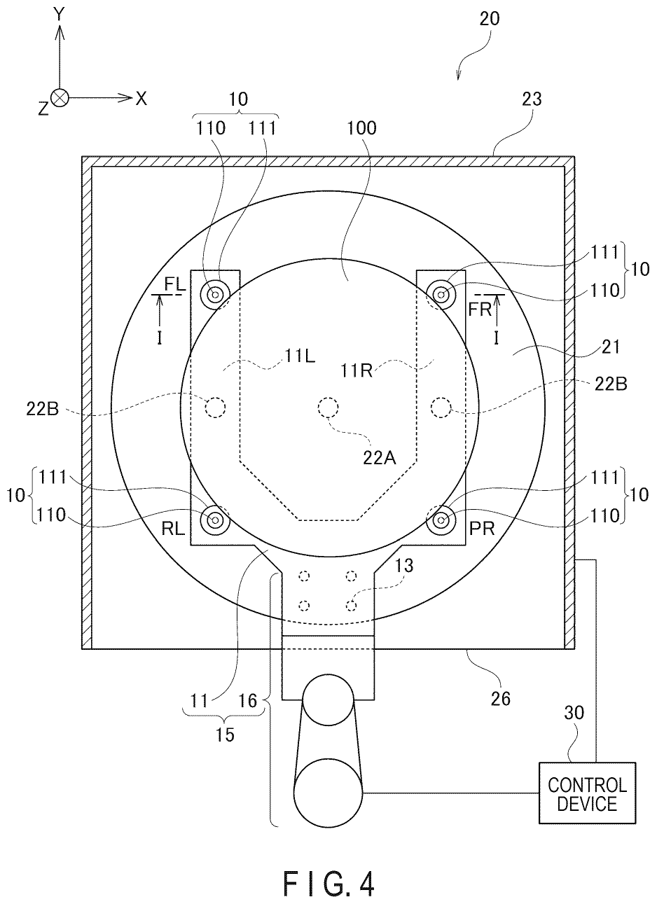

FIG. 4 is a plan view of the transfer portion 11 that transfers the wafers 100 and the holders 10 that hold the wafers 100 in the processing chamber 23, in the semiconductor manufacturing apparatus 20 according to the first embodiment. The holders 10 are attached to the transfer portion 11. In the example in FIG. 4, the wafer 100 is mounted on planar portions 111 of four holders 10.

As shown in FIG. 4, the semiconductor manufacturing apparatus 20 according to the first embodiment includes a transfer device 15, and the processing chamber 23. The transfer device 15 includes the transfer portion 11, and a transfer arm 16. The processing chamber 23 accommodates the transfer portion 11.

The transfer portion 11 is also called a pick for wafer transfer or a transfer blade. The holders 10 fix and hold the wafers 100 on the transfer portion 11. Each holder 10 is also called a pad.

The transfer portion 11 includes a right arm 11R and a left arm 11L. The wafers 100 are held on a first holder FR and a second holder RR provided on the right arm 11R, and a third holder FL and a fourth holder RL provided on the left arm 11L. In the example in FIG. 4, the four holders are arranged. A fifth holder (not shown) may be provided on a joining portion of the right arm 11R and the left arm 11L. Alternatively, a configuration where the wafers 100 are held at three sites that are the first holder FR, the third holder FL, and the fifth holder may be employed.

In the semiconductor manufacturing apparatus 20 according to the first embodiment, for example, the number of transfer portions 11 for wafer transfer is four per apparatus. The number of transfer portions 11 may be one or two.

In the semiconductor manufacturing apparatus 20 according to the first embodiment, for example, the four holders 10 (FL, FR, RL, and RR) are provided per transfer portion 11, and the number of pads per apparatus is 16. Replacement of the holders 10 are executed in a manner where the 16 pads of one transfer component are collectively replaced.

Each holder 10 includes a planar portion 111, and a head portion 110. The contact of the wafer 100 is planar contact with the planar portions 111, and the head portions 110 serve as stoppers for preventing a wafer deviation. As for the planar portions 111, the back surface of the wafer 100 is in contact with the planar portions 111. Ideal wafer placement positions are planar portions at all the four sites FL, FR, RL, and RR. However, at the base portions of the head portions 110, point contact occurs.

### Wafer Transfer Method

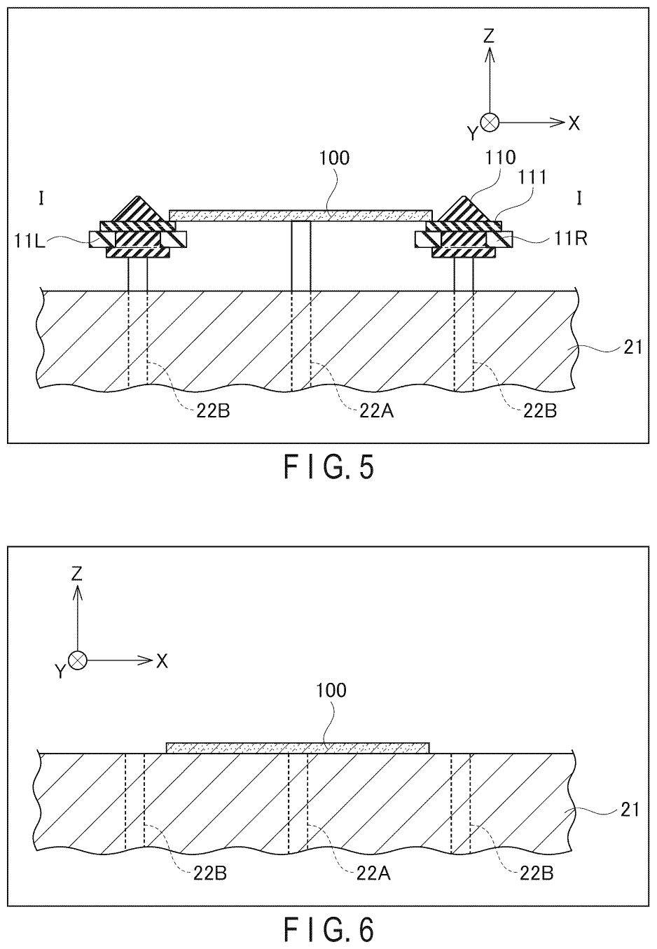

FIG. 5 is a sectional view taken along line I-I in FIG. 4. FIG. 5 is a sectional view for illustrating a transfer method for the wafer 100 in the processing chamber 23 in the semiconductor manufacturing apparatus 20 according to the first embodiment (Part 1). FIG. 6 is a sectional view for illustrating the transfer method for the wafer 100 in the processing chamber 23 in the semiconductor manufacturing apparatus according to the first embodiment (Part 2).

The transfer device 15 includes a transfer arm 16 that is connected to the transfer portion 11 and adjusts the position of the transfer portion 11. The transfer arm 16 is, for example, the robot arm 32 (FIG. 3) that has flexibility in multiple axes. The transfer portion 11 is fixed to the transfer arm 16 with joining pins 13.

The semiconductor manufacturing apparatus 20 further includes a control device 30 that controls the operations of the transfer device 15 and the processing chamber 23. The control device 30 controls the transfer device 15 to store the transfer portion 11 in the processing chamber 23, and execute a process in the processing chamber 23.

In the transfer device 15, the planar portions 111 of the holders 10 positioned on the surface of the transfer portion 11 are areas where the wafer 100 is mounted. FIG. 4 shows a state where the wafer 100 is mounted on the four holders 10 positioned on the surface of the transfer portion 11.

The stage 21 is an area where the wafer 100 stored in the processing chamber 23 is mounted. The wafer pusher pins 22A and 22B are used when the wafer 100 is loaded into the processing chamber 23 and unloads the wafer 100 from the processing chamber 23 by the transfer device 15. For example, when the transfer device 15 loads the wafer 100 into the processing chamber 23, the wafer pusher pins 22A and 22B, whose upper portions are exposed on the upper surface of the stage 21, support the wafer 100 as shown in FIG. 5. In this state, the transfer portion 11 is pulled out from below the wafer 100. Subsequently, the entire wafer pusher pins 22A and 22B are stored in the stage 21. As shown in FIG. 6, the wafer 100 is mounted on the stage 21. On the other hand, when the wafer 100 is unloaded from the processing chamber 23, the upper portions of the wafer pusher pins 22A and 22B are exposed on the upper surface of the stage 21, and the wafer 100 is lifted up. In this state, the transfer portion 11 is inserted below the wafer 100. The entire wafer pusher pins 22A and 22B are then stored in the stage 21, thereby allowing the wafer 100 to be mounted on the transfer portion 11. Subsequently, the transfer device 15 unloads the wafer 100 from the processing chamber 23.

The processing chamber 23 includes a shutter 26 that opens and closes a transfer port through which the transfer portion 11 is transferred into the processing chamber 23. Typically, a manufacturing step in the processing chamber 23 is performed in the processing chamber 23 that is caused to be a sealed space with the shutter 26 being closed. That is, the manufacturing step in the processing chamber 23 executes a step of processing the wafer 100 stored in the processing chamber 23 in the state where the shutter 26 is closed.

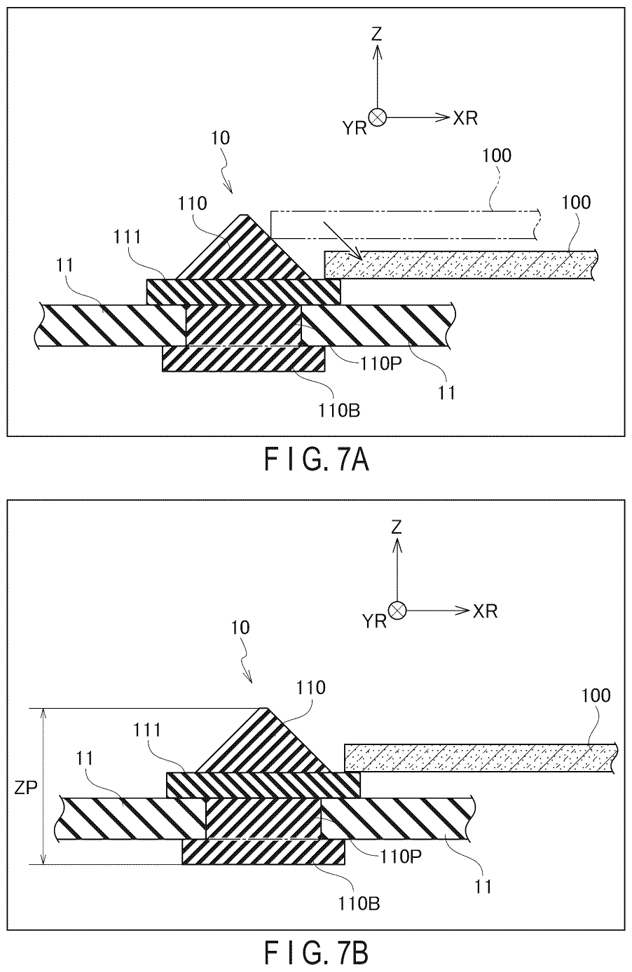

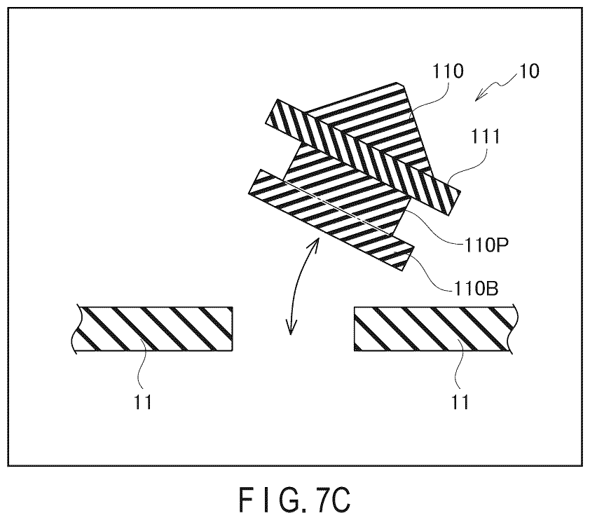

FIG. 7A is a sectional view illustrating the relationship between the holder 10 attached to the transfer portion 11 and the wafer 100 in the semiconductor manufacturing apparatus 20 according to the first embodiment. FIG. 7B is a sectional view of the holder 10 on which the wafer 100 is mounted on the stage 21 in the semiconductor manufacturing apparatus 20 according to the first embodiment.

As shown in FIGS. 7A and 7B, the holder 10 includes a head portion 110, a planar portion 111, a support portion 110P, and a bottom portion 110B. The holders 10 are (e.g., detachably) attached to the transfer portion 11. The wafer 100 is mounted on the planar portion 111 at the wafer end (e.g., outer edge region of the wafer). If the wafer 100 were to be provided on the transfer portion 11 with no planar portion 111, the wafer 100 could move onto the side wall of the head portion as indicated by long dashed double-short dashed lines in FIG. 7A while being transferred, and degrade the side wall of the head portion 110. By providing the planar portion 111, the wafer 100 is prevented from laterally deviating and from moving onto side wall of the head portion 110 while being transferred. As a result, as shown in FIG. 7B, the wafer 100 is stably placed on the planar portion 111 as indicated by solid lines.

Since the holder 10 handles wafers stacked with small gaps, it has a small thickness. The height ZP of the holder 10 in the Z direction is about 5 mm, for example.

The material of the planar portion 111 is a rubber material. The head portion 110 and the planar portion 111 are an integrated component. Thus, the head portion 110 is made of the same material. The thickness of the planar portion 111 is about 0.45 mm, for example.

If a load (press) is applied to a certain site on the holder while the wafer 100 is transferred, the density locally becomes high, and it is hardened. Even with a rubber type material, such as elastomer, a sliding portion (a site where contact repetitively occurs) is hardened. Such smoothing, hardening, and deformation of the surface of the holder defines the lifetime of the holder. The typical lifetime is about 12 months. In the holder 10 applied to the semiconductor manufacturing apparatus 20 according to the first embodiment, the planar portion 111 serves as a contact surface with the wafer 100. Accordingly, the replacement interval can be doubled to 24 months.

A flexible, non-metal material can be used for the holder 10. For example, a rubber type material may be used. In an implementation, a specific material may be elastomer. In the example in FIG. 7A, the head portion 110 has the shape of a cone or a truncated cone with the distal end of the head portion being flat.

FIG. 7C is a diagram illustrating a situation where the holder 10 is attached to and detached from the transfer portion 11 in the semiconductor manufacturing apparatus according to the first embodiment. The holder 10 can be attached to and detached from the transfer portion 11. Depending on the replacement time, the plurality of holders 10 can be replaced from the transfer portion 11 at the same time.

### Modified Example 1 of Holder: Hollow Structure

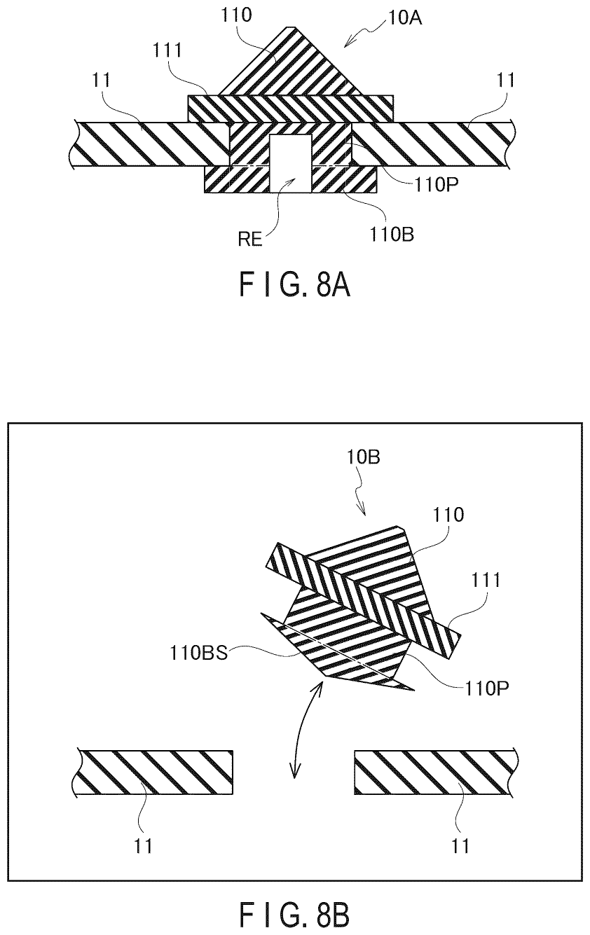

FIG. 8A is a sectional view of the configuration where a holder 10A according to a modified example 1 is attached to the transfer portion 11 in the semiconductor manufacturing apparatus 20 according to the first embodiment. As shown in FIG. 8A, the holder 10A has a recess structure RE in a support portion 110P and a bottom portion 110B (e.g., a support portion recess). By providing such a recess structure RE, the weight of each holder 10A can be reduced. The movement in the transfer of the wafer 100 can be facilitated. Note that the recess structure RE is a hollow structure formed in the support portion 110P and the bottom portion 110B. The hollow structure may be partial. Alternatively, it may be a penetrating one.

### Modified Example 2 of Holder: Bottom Conical Structure

FIG. 8B is a sectional view of a holder 10B according to a modified example 2 and a situation of attachment to and detachment from the transfer portion 11 in the semiconductor manufacturing apparatus 20 according to the first embodiment. As shown in FIG. 8B, the holder 10B has a conical structure having a section with a tapered structure at a bottom portion 110BS. As described above, the shape of the bottom portion 110BS improves the attachment capability of the holder 10B. A flexible, non-metal material can be used for the holder 10B. For example, a rubber type material may be used. Accordingly, the holder 10B can be attached to and detached from the transfer portion 11.

### Modified Example 3 of Holder: Planar Portion Recess Structure

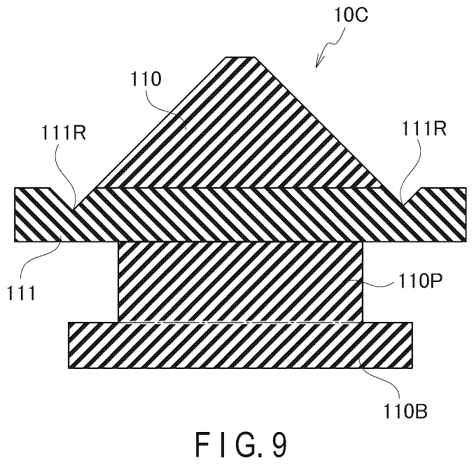

FIG. 9 is a sectional view of the structure of a holder 10C according to a modified example 3 in the semiconductor manufacturing apparatus 20 according to the first embodiment. In the holders 10C according to the modified example 3, a recess 111R (e.g., a planar portion recess) is provided in the planar portion 111. By providing the recess 111R in the peripheral portion of the planar portion 111 that is to be in contact with the head portion 110, dust and other debris caused during the transfer of the wafer 100 can be collected without being dispersed.

According to the first embodiment, the planar portion of each holder is in planar contact with the wafer, and the inclination of the head portion of the holder serves as a stopper. Consequently, the transfer deviation of the wafer is prevented.

### Advantageous Effects of First Embodiment

According to the first embodiment, the semiconductor manufacturing apparatus and the wafer deviation preventing pad can be provided that can prevent the transfer deviation of the wafer, extend the replacement interval of each holder, and reduce the operation man-hour and the cost.

### Second Embodiment: Positioning Structure

A semiconductor manufacturing apparatus according to a second embodiment has positioning structures MPR in the transfer portion 11. For example, in FIG. 4, the transfer portion 11, to which the four holders FL, FR, RL, and RR are attached, is provided with the respective positioning structures MPR.

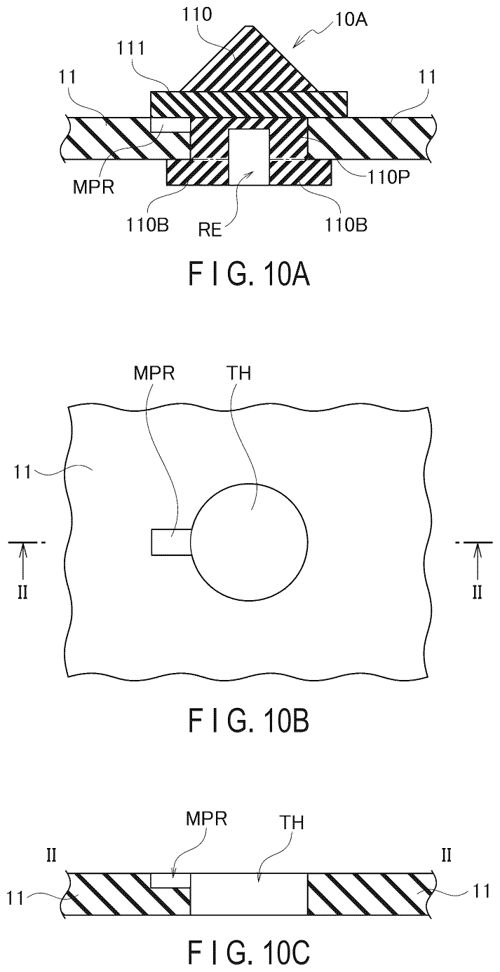

FIG. 10A is a sectional view of a configuration where the holder 10A is attached to the transfer portion 11 that includes the positioning structure MPR. FIG. 10B is a plan view of the transfer portion 11 that has the positioning structure MPR in FIG. 10A. FIG. 10C is a sectional view taken along line II-II in FIG. 10B.

The positioning structure MPR is a recess structure provided on the peripheral portion of a through-hole TH for fixing the holder 10A on the transfer portion 11. The positioning structure MPR is only required to be distinguished from the other area of the transfer portion 11 in plan view. It may be filled with a rubber type material similar to the configuration material of the holder 10A. The other configuration points are similar to those in the first embodiment.

### Advantageous Effects of Second Embodiment

In the semiconductor manufacturing apparatus according to the second embodiment, the transfer portion 11 is provided with the positioning structures MPR, which can improve the attachment capability of the holders 10A to the transfer portion 11. When the holder 10A is rotated to be replaced after attachment and detachment, it can also be used as a positioning marker that avoids the side surface of the used head portion 110.

According to the second embodiment, the semiconductor manufacturing apparatus and the wafer deviation preventing pad can be provided that can prevent the transfer deviation of the wafer, extend the replacement interval of each holder, and reduce the operation man-hour and the cost.

### Third Embodiment: Cutout Cylinder

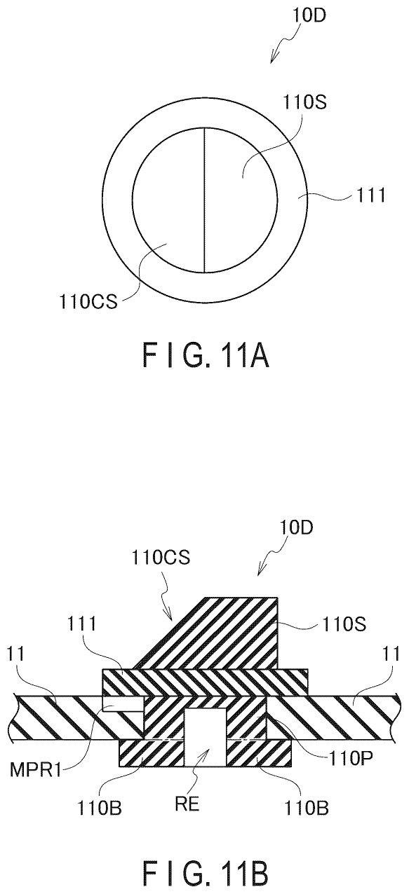

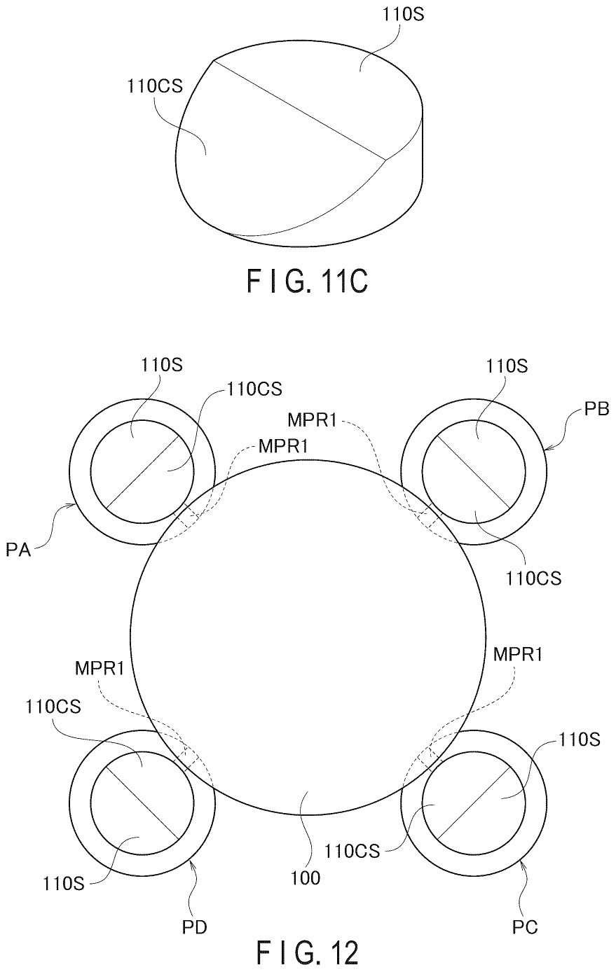

FIG. 11A is a plan view of a holder 10D that includes a cutout cylinder 110S in a semiconductor manufacturing apparatus according to a third embodiment. FIG. 11B is a sectional view of a configuration where the holder 10D is attached to the transfer portion 11 that includes the positioning structure MPR. The plan view and the sectional view of the transfer portion 11 that has the positioning structure in FIG. 11B are represented in manner similar to FIGS. 10B and 10C. FIG. 11C is a three-dimensional configuration diagram of the structure of the head portion of the holder 10D.

The semiconductor manufacturing apparatus according to the third embodiment includes the cutout cylinder 110S at the head portion of the holder 10D. The head portion of the holder 10D has a cutout cylindrical structure that includes a flat surface and an inclined surface (cutout surface) 110CS as the upper surface. As shown in FIG. 11B, the transfer portion 11 is provided with a positioning structure MPR1.

FIG. 12 is a plan view of a configuration where the wafer 100 is mounted on the holder 10D in the semiconductor manufacturing apparatus according to the third embodiment. Although not illustrated in FIG. 12, similar to FIG. 4, the transfer portion 11 is provided with positioning structures MPR1 respectively at the four positions FL, FR, RL, and RR on the transfer portion 11 to which the holder 10D is attached. In the transfer portion 11 to which the holders 10D are attached, the holders FL, FR, RL, and RR at the four positions are respectively called PA, PB, PC, and PD. As shown in FIGS. 11B and 12, in plan view, the inclined surfaces 110CS of the holders PA, PB, PC, and PD, and the positioning structure MPR1, MPR2, MPR3, and MPR4 are arranged at the positions that face each other. The other configuration points are similar to those in the first embodiment.

In the semiconductor manufacturing apparatus according to the third embodiment, the holder 10D has the recess structures RE provided in the support portion 110P and the bottom portion 110B in a manner similar to that of the holder 10A according to the modified example 1 shown in FIG. 10A. By providing such a recess structure RE, the weight of each holder 10D can be reduced. The positioning structure MPR is provided at the peripheral portion of the through-hole TH for fixing the holder 10D that is attached to the transfer portion 11. The positioning structure MPR may be filled with a rubber type material similar to the configuration material of the holder 10D. The other configuration points are similar to those in the second embodiment.

### Advantageous Effects of Third Embodiment

In the semiconductor manufacturing apparatus according to the third embodiment, the transfer portion 11 is provided with the positioning structures MPR, which can improve the attachment capability of the holders 10D to the transfer portion 11.

According to the third embodiment, the semiconductor manufacturing apparatus and the wafer deviation preventing pad can be provided that can prevent the transfer deviation of the wafer, extend the replacement interval of each holder, and reduce the operation man-hour and the cost.

### Fourth Embodiment: Positioning Structure

In a semiconductor manufacturing apparatus according to a fourth embodiment, the transfer portion 11, to which the holders 10A according to the modified example 1 are attached, is provided with positioning structures MPR1, MPR2, MPR3, and MPR4 respectively at the four positions at the peripheral portion of a through-hole TH.

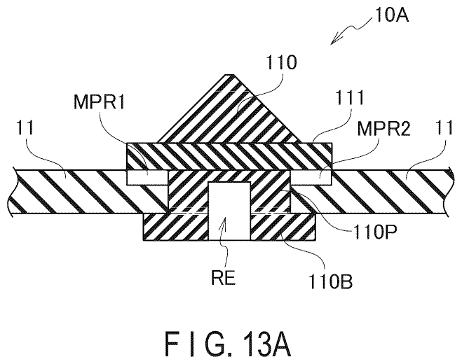

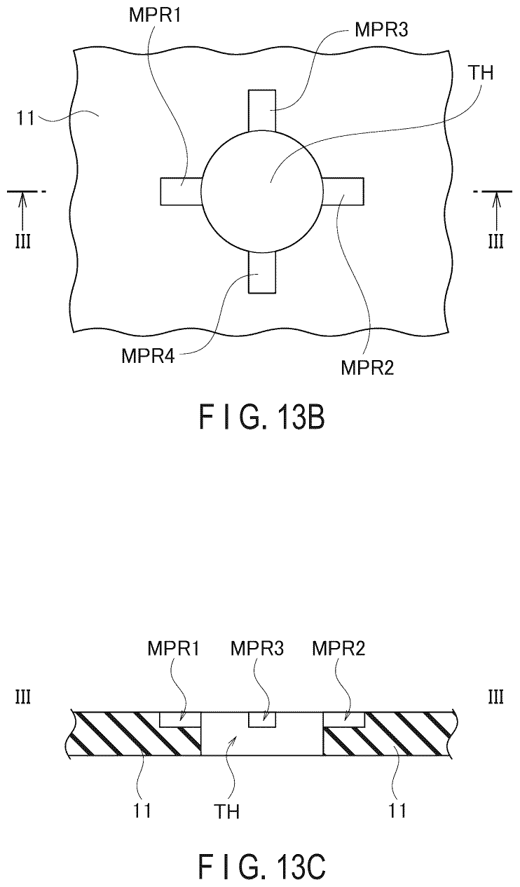

FIG. 13A is a sectional view of the configuration where a holder 10A according to a modified example 1 is attached to the transfer portion 11 in the semiconductor manufacturing apparatus according to the fourth embodiment. FIG. 13B is a plan view of the transfer portion 11 that includes the positioning structures MPR1, MPR2, MPR3, and MPR4. FIG. 13C is a sectional view taken along line III-III in FIG. 13B.

As shown in FIG. 13B, the transfer portion 11, to which the holders 10A are attached, is provided with the positioning structures MPR1, MPR2, MPR3, and MPR4 at the peripheral portion of the through-hole TH. As shown in FIG. 13B, the positioning structures MPR1, MPR2, MPR3, and MPR4 are arranged to form a cross structure to face each other. As shown in FIGS. 13A to 13C, the positioning structures MPR1 and MPR2 are arranged on a line, and face each other. Likewise, the positioning structures MPR3 and MPR4 are arranged on a line, and face each other. The other configuration points are similar to those in the second embodiment.

### Application Examples

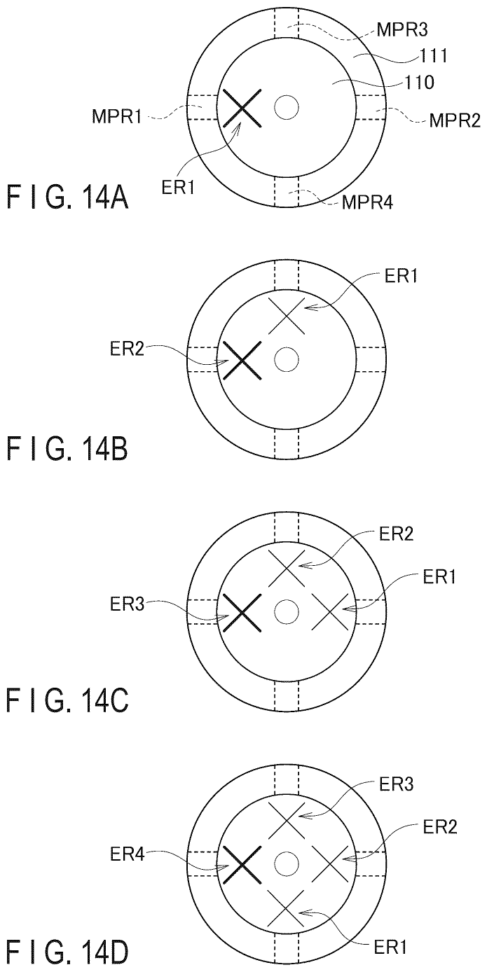

FIGS. 14A to 14D are plan views showing first to fourth application examples of a holder 10A according to the modified example 1 in the semiconductor manufacturing apparatus according to the fourth embodiment.

In FIG. 14A, an example where a side wall portion of the head portion 110 of the conical structure corresponding to the positioning structure MPR1 has deteriorated is schematically indicated by ER1 with a symbol of x. To effectively utilize the holder 10A in such a case, the holder 10A may be rotated clockwise by 90 degrees, and reused.

In FIG. 14B, an example where side wall portions of the head portion 110 corresponding to the positioning structures MPR1 and MPR3 have deteriorated is schematically indicated by ER1 and ER2 with symbols of x. To further effectively utilize the holder 10A in such a case, the holder 10A may be rotated clockwise by 90 degrees, and reused.

In FIG. 14C, an example where side wall portions of the head portion 110 corresponding to the positioning structures MPR1, MPR3, and MPR2 have deteriorated is schematically indicated by ER1, ER2, and ER3 with symbols of x. To further effectively utilize the holder 10A in such a case, the holder 10A may be rotated clockwise by 90 degrees, and reused.

In FIG. 14D, an example where side wall portions of the head portion 110 corresponding to the positioning structures MPR1, MPR3, MPR2, and MPR4 have deteriorated is schematically indicated by ER1, ER2, ER3, and ER4 with symbols of x. The holder 10A is to be replaced only in the state where all the side wall portions in the four directions have finally deteriorated as shown in FIG. 14D. As a result, a four-fold lifetime is achieved.

The application examples 1 to 4 in FIGS. 14A to 14D can be similarly applied to each of the holders PA, PB, PC, and PD arranged on the transfer portion 11.

### Advantageous Effects of Fourth Embodiment

In the semiconductor manufacturing apparatus according to the fourth embodiment, the transfer portion 11 is provided with the positioning structures MPR, which can improve the attachment capability of the holders 10A to the transfer portion 11. Furthermore, by rotating each holder 10A and using it, the holder 10A can be effectively utilized. In the case of rotating the holder 10A for use, the positioning structure can also be used as a positioning marker for avoiding the used side surface of the head portion 110.

According to the fourth embodiment, the semiconductor manufacturing apparatus and the wafer deviation preventing pad can be provided that can prevent the transfer deviation of the wafer, extend the replacement interval of each holder, and reduce the operation man-hour and the cost.

### Fifth Embodiment: Recess Structure

The semiconductor manufacturing apparatus according to the fifth embodiment includes a head portion 110RE where a recess structure RES is formed on a side wall surface corresponding to a generatrix of the cone at the holder 10A according to the modified example 1.

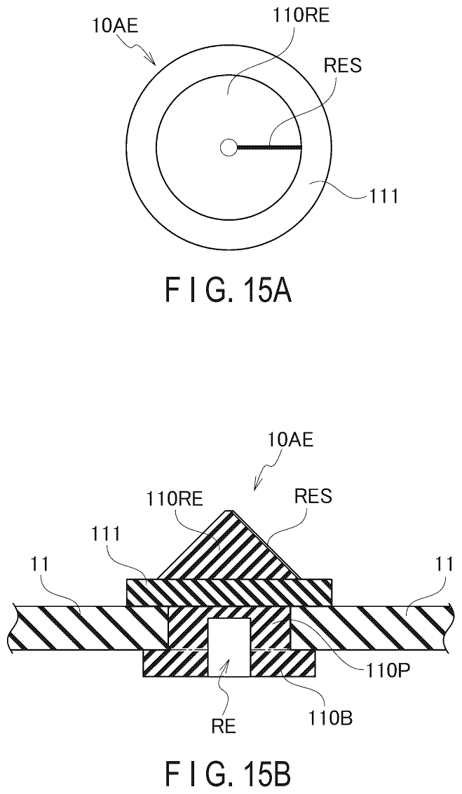

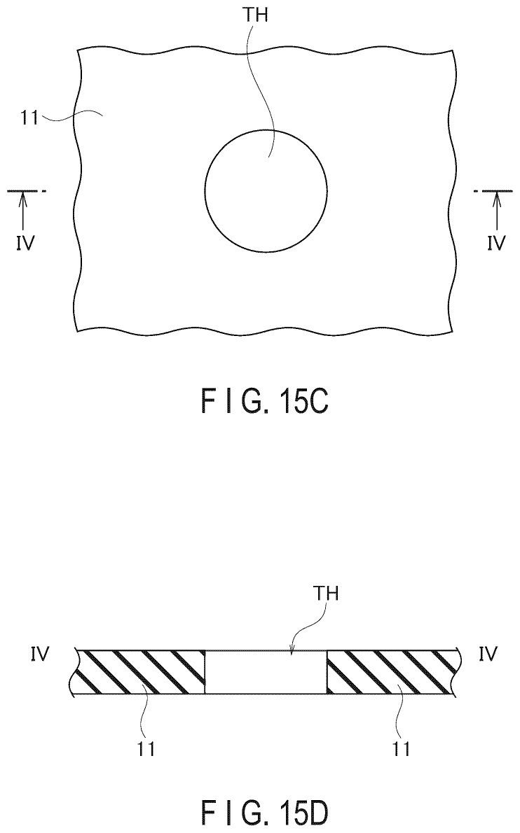

FIG. 15A is a plan view of the configuration of a holder 10AE that includes a head portion 110RE where a recess structure RES is formed. As shown in FIG. 15A, the recess structure RES is formed from the apex to the base of the cone of the head portion 110RE on the side wall surface of the cone. The recess structure RES serves as a marker position of the holder 10AE.

FIG. 15B is a sectional view of the configuration where the holder 10AE is attached to the transfer portion 11. Similar to the holder 10A according to the modified example 1, the holder 10AE has the recess structure RE in the support portion 110P and the bottom portion 110B. By providing such a recess structure RE, the weight of each holder 10AE can be reduced.

FIG. 15C is a plan view of the transfer portion 11 in FIG. 15B. FIG. 15D is a sectional view taken along line IV-IV in FIG. 15C. As shown in FIGS. 15C and 15D, in the transfer portion 11, a through-hole TH is formed. The peripheral portion of the through-hole TH is not specifically provided with any positioning structure.

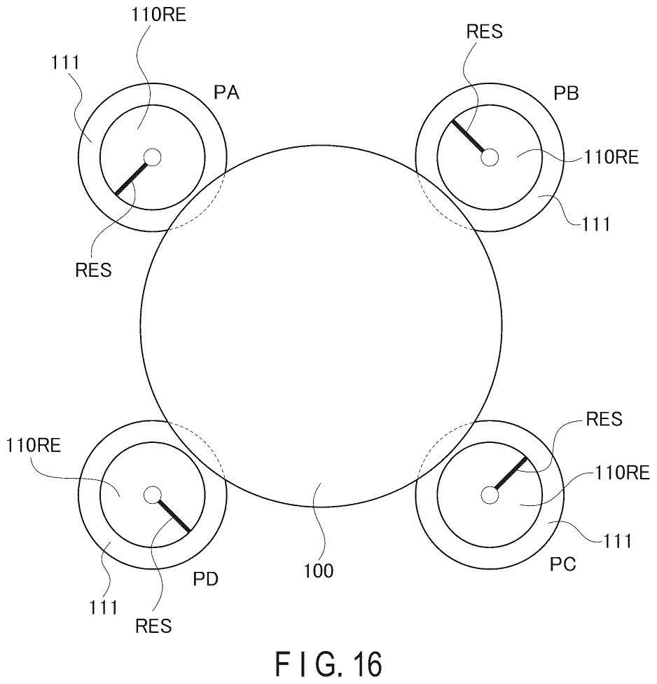

FIG. 16 is a plan view of a configuration where the wafer 100 is mounted on the holders 10AE in the semiconductor manufacturing apparatus according to the fifth embodiment. Although the transfer portion 11 is not illustrated in FIG. 16, similar to FIG. 4, the holders 10AE that can use the recess structures RES as positioning markers are provided as the holders FL, FR, RL, and RR at the four positions on the transfer portion 11. In the transfer portion 11 to which the holders 10AE are attached, the holders FL, FR, RL, and RR at the four positions are respectively called PA, PB, PC, and PD.

As shown in FIG. 16, the recess structures RES of the holders PA, PB, PC, and PD are arranged to be laid in certain directions in plan view. For example, with the holder PA, the recess structure RES is provided at a position rotated clockwise by 90 degrees from the contact point with the wafer 100. Likewise, with each of the other holders PB, PC, and PD, the recess structure RES is provided at a position rotated clockwise by 90 degrees from the contact point with the wafer 100. The other configuration points are similar to those in the second embodiment.

### Application Examples

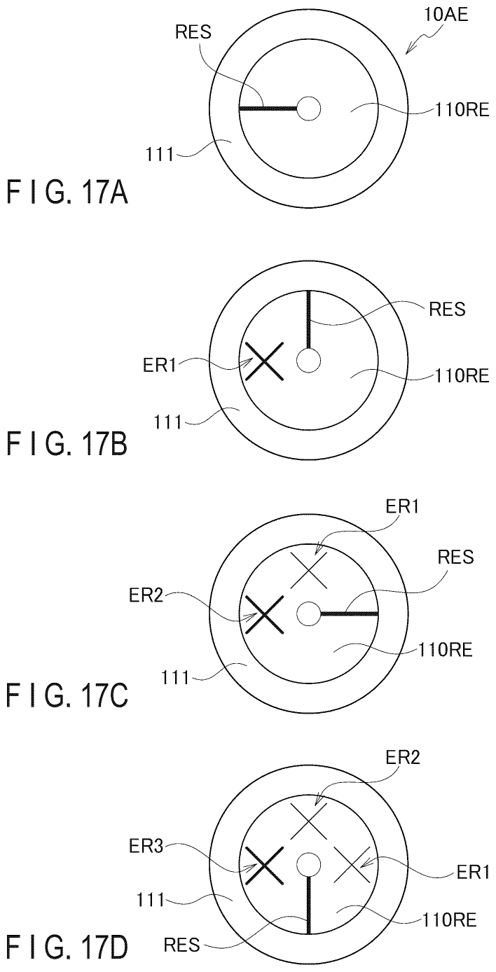

FIG. 17A is a plan view showing a first application example of the holder 10AE in the semiconductor manufacturing apparatus according to the fifth embodiment. On the other hand, FIGS. 17B to 17D are plan views showing second to fourth application examples of the holder 10AE in the semiconductor manufacturing apparatus according to the fifth embodiment.

In FIG. 17B, an example where a side wall portion of the head portion 110RE at a position 90 degrees counterclockwise from the recess structure RES has deteriorated is schematically indicated by ER1 with a symbol of x. To effectively utilize the holder 10AE in such a case, the holder 10AE may be rotated clockwise by 90 degrees, and reused.

In FIG. 17C, an example where a side wall portion of the head portion 110RE at a position 180 degrees counterclockwise from the recess structure RES has deteriorated is schematically indicated by ER2 with a symbol of x. To further effectively utilize the holder 10A in such a case, the holder 10AE may be rotated clockwise by 90 degrees, and reused.

In FIG. 17D, an example where a side wall portion of the head portion 110RE at a position 90 degrees clockwise from the recess structure RES has deteriorated is schematically indicated by ER3 with a symbol of x. To further effectively utilize the holder 10A in such a case, the holder 10AE may be rotated clockwise by 90 degrees, and reused. That is, it may be returned to FIG. 17A. The holder 10AE is to be replaced only in the state where all the side wall portions in the four directions have finally deteriorated. As a result, a four-fold lifetime is achieved.

The application examples 1 to 4 in FIGS. 17A to 17D can be similarly applied to each of the holders PA, PB, PC, and PD arranged on the transfer portion 11.

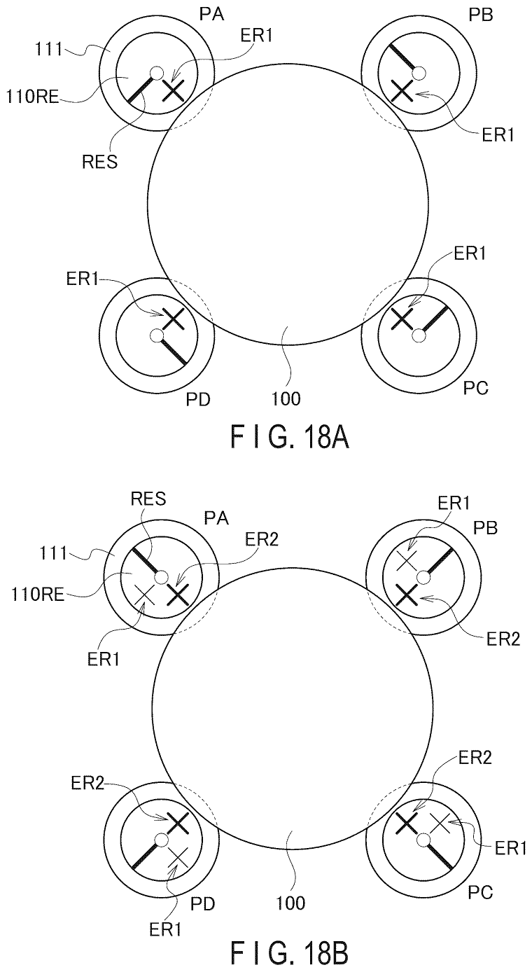

FIG. 18A is a plan view of a configuration where the holders 10AE are applied to the holders PA, PB, PC, and PD, and the wafer is mounted in the semiconductor manufacturing apparatus according to the fifth embodiment (first application example).

In FIG. 18A, an example where side wall portions of the head portions 110RE at positions 90 degrees counterclockwise respectively from the recess structures RES have deteriorated is schematically indicated by ER1 with symbols of x on the holders PA, PB, PC, and PD. To effectively utilize the four holders 10AE in such a case, the four holders 10AE may be rotated clockwise by 90 degrees, and reused.

FIG. 18B is a plan view of a configuration where the holders 10AE are applied to the holders PA, PB, PC, and PD, and the wafer is mounted in the semiconductor manufacturing apparatus according to the fifth embodiment (second application example).

In FIG. 18B, an example where side wall portions of the head portions 110RE at positions 180 degrees counterclockwise respectively from the recess structures RES have deteriorated is schematically indicated by ER2 with symbols of x. To further effectively utilize the holder 10A in such a case, similar to FIG. 17C, the holder 10AE may be rotated clockwise by 90 degrees, and reused. All the four holders 10AE at the holders PA, PB, PC, and PD are to be replaced only in the state where all the side wall portions in the four directions have finally deteriorated. As a result, a four-fold lifetime is achieved.

### Advantageous Effects of Fifth Embodiment

In the semiconductor manufacturing apparatus according to the fifth embodiment, any positioning structure is not required to be formed on the transfer portion 11, and it is only required to perform simple circular processing, thus facilitating the processing. By forming the recess structure RES on the side wall portion of the head portion 110RE, it can be used as the marker. Furthermore, by rotating each holder 10AE and using it, the holder 10AE can be effectively utilized. By using the recess structure RES on the side wall portion of the head portion 110RE as the positioning structure, it can also be used as the positioning marker to avoid the used side surface of the head portion 110RE when the holder 10AE is rotated and used.

According to the fifth embodiment, the semiconductor manufacturing apparatus and the wafer deviation preventing pad can be provided that can prevent the transfer deviation of the wafer, extend the replacement interval of each holder, and reduce the operation man-hour and the cost.

In case a wafer deviation occurs at the holder of the transfer portion of the semiconductor manufacturing apparatus, there is a possibility that the wafer falls from the transfer portion, the wafer collides with the processing chamber into which the wafer is to be loaded, and the wafer is broken. To arrange the wafer on the transfer portion again, it is required to stop the steps. In case the wafer deviation occurs as described above, the productivity decreases in the fabrication of the semiconductor device.

The semiconductor manufacturing apparatuses according to the first to fifth embodiments can extend the lifetime of replacement of each holder. As a result, the productivity of the fabrication of the semiconductor device can be prevented from decreasing.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. The accompanying claims and their equivalents are intended to cover such forms or modification as would fall within the scope and spirit of the inventions.

What is claimed is

1. A semiconductor manufacturing apparatus, comprising:
a storage chamber that stores a wafer;
a robot that unloads the wafer from the storage chamber, and transfers the wafer to a processing chamber;
a robot arm attached to the robot;
a transfer portion that is attached to the robot arm and transfers the wafer; and
a plurality of holders that are attached to the transfer portion and hold the wafer, wherein
each holder of the plurality of holders includes a planar portion; and a head portion on the planar portion, and
an outer end of the wafer is in planar contact with the planar portion, and the head portion is configured to prevent a wafer deviation.

2. The semiconductor manufacturing apparatus of claim 1, wherein:
the transfer portion includes a through-hole therein, and
the holder is attached to the transfer portion via the through-hole.

3. The semiconductor manufacturing apparatus of claim 2, wherein the holder is detachable from the through-hole and is replaceable.

4. The semiconductor manufacturing apparatus of claim 1,
wherein the transfer portion includes a right arm and a left arm, and
wherein the wafer is transferred while being held on:
a first holder of the plurality of holders, the first holder being on the right arm, and
a second holder of the plurality of holders, the second holder being on the left arm.

5. The semiconductor manufacturing apparatus of claim 2, wherein the through-hole has a positioning structure at a peripheral portion.

6. The semiconductor manufacturing apparatus of claim 5, wherein the positioning structure is at a cross position on the peripheral portion in plan view.

7. The semiconductor manufacturing apparatus of claim 2, wherein:
the holder includes:
an upper portion configured to hold the wafer; and
a lower portion configured to be attached to the transfer portion via the through-hole,
the upper portion includes the planar portion and the head portion, and
the lower portion includes:
a support portion that penetrates through the transfer portion and supports the upper portion; and
a bottom portion that is connected to the support portion and is attached to the transfer portion.

8. A wafer deviation preventing pad that is a pad that is attached to a transfer portion for transferring a wafer and that holds the wafer, the wafer deviation preventing pad comprising:
a planar portion;
a head portion on the planar portion;
a support portion that penetrates through the transfer portion and supports the planar portion; and
a bottom portion that is connected to the support portion and supports the support portion,
wherein
the planar portion is configured to be in planar contact with an outer end of the wafer, and
the head portion is configured to prevent a transfer deviation.

9. The wafer deviation preventing pad of claim 8, wherein the transfer portion is formed with a through hole having an inner diameter corresponding to an outer diameter of the support portion of the pad.

10. A wafer deviation preventing pad, comprising:
an upper portion configured to hold a wafer; and
a lower portion configured to be attached to a transfer portion via a through-hole, wherein
the upper portion includes a planar portion; and a head portion on the planar portion,
the lower portion includes a support portion that penetrates through the transfer portion and supports the upper portion; and a bottom portion that is connected to the support portion, and attaches the upper portion and the support portion to the transfer portion, and
the planar portion is configured to be in planar contact with an outer end of the wafer, and the head portion is configured to prevent a transfer deviation.

11. The wafer deviation preventing pad of claim 10, wherein:
the head portion has a conical structure, and
the head portion is configured to be in point contact with the outer end of the wafer.

12. The wafer deviation preventing pad of claim 10, wherein:
the head portion has a cutout cylindrical structure, and
the head portion is configured to be in point contact with the outer end of the wafer.

13. The wafer deviation preventing pad of claim 11, wherein the conical structure has a recess in an inclined surface thereof.

14. The wafer deviation preventing pad of claim 10, wherein the bottom portion and the support portion together include a hollow structure therein.

15. The wafer deviation preventing pad of claim 10, wherein the bottom portion has a conical shape that is convex downward.

16. The wafer deviation preventing pad of claim 11, wherein the planar portion includes a recess structure therein at a base portion of the conical structure.
